(19) United States
(12) Patent Application Publication
(10) Pub. No.: US 2006/0063032 A1
(43) Pub. Date: Mar. 23, 2006

(54) Organic electroluminescent device

(76) Inventor: Noriyuki Matsusue, Osaka (JP)

Correspondence Address: MCDERMOTT WILL & EMERY LLP, 600 13TH STREET, N.W., WASHINGTON, DC, 20005-3096, US

(21) Appl. No.: 11/091,948

(22) Filed: Mar. 29, 2005

(30) Foreign Application Priority Data
Mar. 29, 2004 (JP) 2004-096121

(51) Int. Cl. H01L 51/54; H05B 33/14

(52) U.S. Cl. 428/690; 428/917; 313/504; 257/102; 257/E51.044

(57) ABSTRACT

A hole injection electrode made of a transparent conductive film is formed on a substrate made of indium-tin oxide (ITO) or the like. On the hole injection electrode, a hole injection layer, a hole transport layer, a light emitting layer, an electron transport layer, and an electron injection layer are formed in order. On the electron injection layer, an electron injection electrode made of aluminum is formed. The light emitting layer includes a first dopant made of a material capable of converting triplet excitation energy to an emission of a predetermined color and a second dopant made of a material capable of converting single excitation energy to an emission of the same color as the predetermined color. The difference between the emission peak wavelength of the first dopant and the emission peak wavelength of the second dopant is preferably 20 nm or less.

### BACKGROUND OF THE INVENTION

1. Field of the Invention

The present invention relates to an organic electroluminescent device.

2. Description of the Background Art

Organic electroluminescent (hereinafter referred to as organic EL) devices are considered promising as new type of self-emitting devices. An organic EL device has a layered structure including in order a hole transport layer, a light emitting electrode, and an electron transport layer between a hole injection electrode and an electron injection electrode.

An electrode material with a large work function such as gold or indium tin oxide (ITO) is used as the hole injection electrode, and an electrode material with a small work function such as magnesium or lithium is used as the electron injection electrode.

When voltage is applied between the hole injection electrode and the electron injection electrode in the organic EL device, holes are injected from the hole injection electrode and electrons are injected from the electron injection electrode. The injected holes and electrons, respectively, pass through the hole transport layer and the electron transport layer and then injected into the light emitting layer, where they are recombined to form excitons and produce light.

Most of the organic EL devices suggested today use singlet excitons to emit light (fluorescence), and do not use triplet excitons to emit light (phosphorescence). According to a quantum mechanical view, singlet excitons and triplet excitons are formed with a probability of 1:3. The foregoing shows that in organic EL devices using singlet excitation energy produced by singlet excitons alone, only 25% of the entire formed excitation energy is utilized for light emission. This results in low luminous efficiencies of the organic EL devices.

In one suggested method, tris(2-phenylpyridine)iridium (hereinafter abbreviated to Ir(ppy)3), an example of ortho-metalated complexes, is used as a luminescent material (refer to M. A. Baldo et al., Applied Physics Letters, Vol. 75, No. 1, p 4, (1999)), in order to allow triplet excitation energy produced by triplet excitons to contribute to light emission. With this method, long life, high efficiency green light emission can be obtained with a luminous efficiency of two to three times that of conventional organic EL devices using singlet excitation energy alone for light emission.

Also suggested is an organic EL device that includes a light emitting layer doped with a material allowing triplet excitation energy to contribute to light emission (hereinafter referred to as a triplet material) and a material allowing singlet excitation energy to contribute to light emission (hereinafter referred to as a singlet material) (refer to e.g. JP 2003-77674 A and M. A. Baldo et al., Applied Physics Letters, Vol. 81, No. 8, p 1509, (2002)).

M. A. Baldo et al., Applied Physics Letters, Vol. 81, No. 8, p 1509, (2002), in particular, offers red light emission with high efficiency. This is achieved by doping polyvinylcarbazole (PVK) having a relatively great energy gap (Eg) of 3.5 eV between the lowest unoccupied molecular orbit (LUMO) level and the highest occupied molecular orbit (HOMO) level with a triplet material, Ir(ppy)3, having an energy gap of 2.7 eV and a singlet material, nile red, having an energy gap of 1.7 eV.

However, the conventional methods described above do not provide organic EL devices with sufficiently long life and high efficiency. They fail to realize, in particular, organic EL devices which emit blue light with long life and high efficiency. That is, not all of the organic EL devices that can emit colors of R (red), G (green), and B (blue), respectively, satisfying the luminous efficiency and life needed to achieve a full-color display, have been developed.

### SUMMARY OF THE INVENTION

An object of the present invention is to provide a high efficiency and long life organic electroluminescent device.

According to the present invention there is provided an organic electroluminescent device comprising a light emitting layer between a first electrode and a second electrode, wherein the light emitting layer includes a first dopant made of a material capable of converting at least triplet excitation energy to an emission of a predetermined color and a second dopant made of a material capable of converting singlet excitation energy to an emission of the same color as the predetermined color.

The inclusion of the first dopant with high luminous efficiency and the chemically stable second dopant in the organic electroluminescent device of the invention enables high lumionous efficiency and extended life of the organic electroluminescent device.

The predetermined color may be blue. In this case, blue light emission with high luminous efficiency and long life is realized.

It is preferable that a difference between an emission peak wavelength of the first dopant and an emission peak wavelength of the second dopant is 20 nm or less. This prevents the light emitting layer from emitting in a different color from the predetermined color.

The emission peak wavelength of the first dopant may be smaller than the emission peak wavelength of the second dopant. This facilitates the emission of the second dopant with a smaller energy gap, allowing the first dopant with high luminous efficiency and the chemically stable second dopant to contribute almost equally to light emission. This results in light emission with high efficiency and long life.

The first dopant may be an ortho-metalated complex. The use of an ortho-metalated complex as the first dopant results in an organic electroluminescent device with high efficiency and long life.

The ortho-metalated complex may have a molecular structure shown in the formula (1) below: 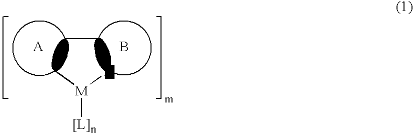
where a ring A is an aromatic hydrocarbon ring that may have a substituent or an aromatic heterocycle that may have a substituent; a group of the ring A and a group of the ring B may bond to form a ring that is fused to the ring A and the ring B; M is a platinum group element; L is a ligand; a value represented by m+n (m and n being integers) is equal to the valence of the platinum group element; and n represents an integer of 0≦n<m+n.

m in the formula (1) may be two, and L may have a molecular structure shown in the formula (L1) below: 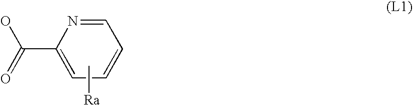
where Ra is a hydrogen atom, a halogen atom or a substituent.

m in the formula (1) may be two, and L may have a molecular structure shown in the formula (L2) below: 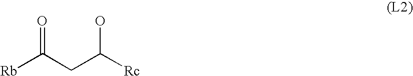
where Rb and Rc are the same or different, each being a hydrogen atom, a halogen atom or a substituent.

It is preferable that the platinum group element is iridium, platinum, osmium, ruthenium, rhodium or palladium.

It is preferable that the second dopant is a styryl compound, an anthracene derivative or a perylene derivative. The use of a styryl compound, an anthracene derivative or a perylene derivative as the second dopant results in an organic electroluminescent device with high efficiency and long life.

The styryl compound has a molecular structure shown in the formula (2) below:

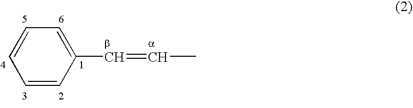

A sum of contents of the first and the second dopants in the light emitting layer may be not more than 1 wt % and not less than 50 wt % of the host material. This allows the first and the second dopants in the light emitting layer to function not as a host but as dopants.

According to the present invention, an organic electroluminescent device with high efficiency and long life can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross section showing an example of an organic EL device according to an embodiment of the invention; and

FIG. 2 is a schematic diagram showing exemplified energy levels of the lowest unoccupied molecular orbits (LUMO) and the highest occupied molecular orbits (HOMO) for the hole transport layer, light emitting layer, and electron transport layer in the organic EL device of the embodiment as well as exemplified transfer processes of holes and electrons.

### DESCRIPTION OF THE PREFERRED EMBODIMENTS

An organic electroluminescent (hereinafter referred to as an organic EL) device according to the present invention will now be described with reference to the drawings.

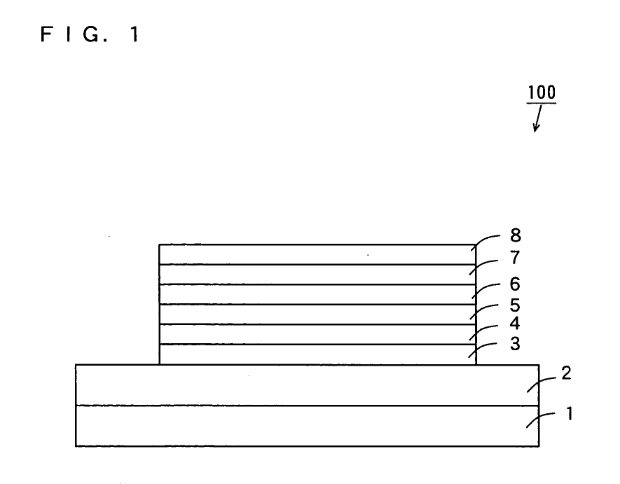

FIG. 1 is a schematic cross section showing an example of the organic EL device according to an embodiment of the invention.

In fabricating the organic EL device 100 shown in FIG. 1, a hole injection layer 2 made of a transparent conductive film such as indium-tin oxide (ITO) is formed first on a substrate 1, and then on the hole injection electrode 2, a hole injection layer 3, a hole transport layer 4, a light emitting layer 5, an electron transport layer 6, and an electron injection layer 7 are formed in order. Following this, an electron injection electrode 8 of aluminum, for example, is formed on the electron injection layer 7. The substrate 1 is a transparent substrate made of glass or plastic, for example.

The hole injection layer 3 is made of an organic material such as copper phthalocyanine (hereinafter abbreviated to CuPc), for example, having a molecular structure shown in the formula (3) below. The hole injection layer 3 has a thickness of 100 Å, for example.

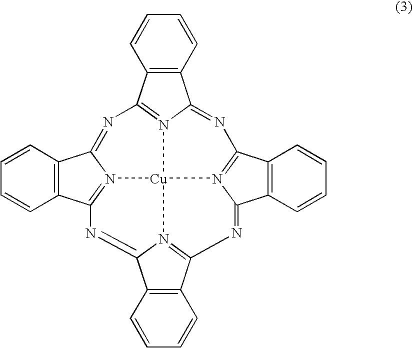

The hole transport layer 4 is made of an organic material such as N,N′-Di(naphthalene-1-yl)-N,N′-diphenyl-benzidine (hereinafter abbreviated to NPB), for example, having a molecular structure shown in the formula (4) below. The hole transport layer 4 has a thickness of 500 Å, for example.

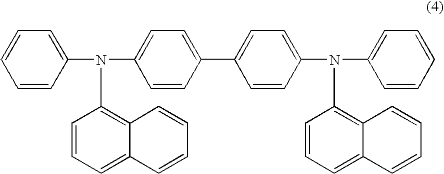

The light emitting layer 5 includes a host material, a first dopant made of a triplet material, and a second dopant made of a singlet material. The light emitting layer 5 has a thickness of 250 Å, for example. As used herein, the term triplet material refers to an organic material allowing triplet excitation energy to contribute to light emission (i.e., convert it to light emission), and the term singlet material refers to an organic material allowing singlet excitation energy to contribute to light emission.

The host material of the light emitting layer 5 is made of an organic material such as 4,4′-Bis(carbazol-9-yl)-biphenyl (hereinafter abbreviated to CBP), for example, having a molecular structure shown in the formula (5) below. The CBP has an energy gap (Eg) of 3.5 eV between the lowest unoccupied molecular orbit (LUMO) level and the highest occupied molecular orbit (HOMO) level, and a emission peak wavelength λ_{MAX} of 400 nm.

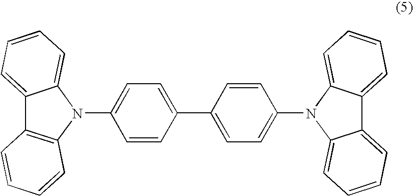

The first dopant of the light emitting layer 5 which is made of a triplet material is an ortho-metalated complex, for example, having a molecular structure shown in the formula (1) below: 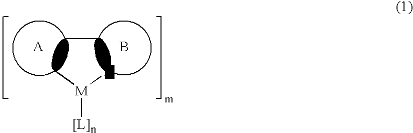
where the ring A is an aromatic hydrocarbon ring that may have a substituent or an aromatic heterocycle that may have a substituent, and the ring B is an aromatic heterocycle that may have a substituent. A group of the ring A and a group of the ring B may bond to form a ring fused to the ring A and ring B. Note also that M is a platinum group element; L is a bidentate ligand; the value represented by m+n (m and n being integers) is equal to the valence of the platinum group element; and n represents an integer of 0≦n<m+n.

The ring A in the formula (1) is a thiophene ring, benzene ring, diazole ring, thiazole ring, oxazole ring, thiadiazole ring, oxadiazole ring, triazole ring, pyridine ring, diazine ring, triazine ring, or the like, that may have a substituent. It is particularly preferable that the ring A is a thiophene ring or a benzene ring.

It is also preferable that the ring B in the formula (1) is a thiazole ring, benzene ring, pyridine ring, diazine ring, triazine ring, or the like, that may have a substituent. It is particularly preferable that the ring B is a pyridine ring or a thiazole ring.

Examples of the platinum group element M in the formula (1) include iridium (Ir), platinum (Pt), osmium (Os), ruthenium (Ru), rhodium (Rh), or palladium (Pd). It is particularly preferable that the platinum group element M is iridium or platinum. This results in higher luminous efficiency.

In the case where m in the formula (1) is two, L has a molecular structure shown in the formula (L1) below, for example:

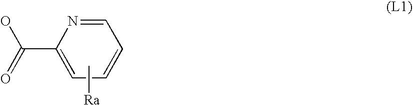

In the case where m in the formula (1) is two, L has a molecular structure shown in the formula (L2) below, for example:

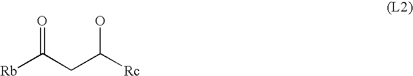

In the formulas (L1) and (L2), Ra, Rb, Rc are each a hydrogen atom, a halogen atom, or a substituent. Examples of Ra, Rb, Rc include —CₙH₂ₙ₊₁ (n=0 to 10), a phenyl group, naphthyl group, thiophene group, furyl group, dienyl group, —CN, —N(CₙH₂ₙ₊₁)₂ (n=1 to 10), —COOCₙH₂ₙ₊₁ (n=1 to 10), —F, —Cl, —Br, —I, —CF₃, —OCH₃, and —OC₂H₅ or the like.

In the present embodiment, an iridium complex is employed whose platinum group element M in the formula (1) is iridium. As an example of the above-mentioned iridium complex, bis[4,6-difluorophenyl]-pyridinato-N,C2 Iridium(picolinato) (hereinafter abbreviated to FIrpic) having a molecular structure shown in the formula (6) below is employed for the first dopant of the light emitting layer 5 in the present embodiment. The FIrpic has an energy gap (Eg) of 3.0 eV between the lowest unoccupied molecular orbit (LUMO) level and the highest occupied molecular orbit (HOMO) level, and a emission peak wavelength of λ_{MAX} of 470 nm. The light emitting layer 5 is doped with 6.5 wt % FIrpic.

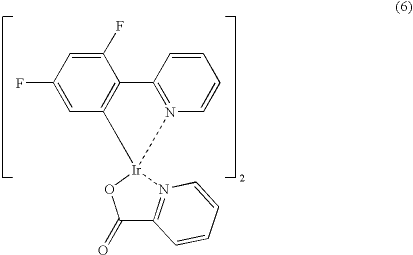

The second dopant of the light emitting layer 5 which is made of a singlet material is a styryl compound, for example, having a molecular structure shown in the formula (2) below:

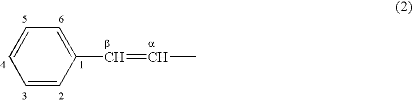

As an example of the above-mentioned styryl compound, 4,4-Bis(2,2-diphenyl-ethen-1-yl)-biphenyl (hereinafter abbreviated to DPVBi) having a molecular structure shown in the formula (7) below is employed for the second dopant of the light emitting layer 5 in the present embodiment. The DPVBi has an energy gap (Eg) of 3.1 eV between the lowest unoccupied molecular orbit (LUMO) level and the highest occupied molecular orbit (HOMO) level, and a emission peak wavelength of λ_{MAX} of 480 nm. The light emitting layer 5 is doped with 2.5 wt % DPVBi.

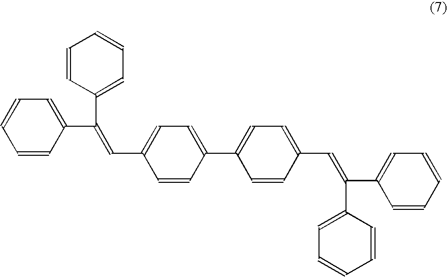

The electron transport layer 6 is made of an organic material such as ((1,1+-Bisphenyl)-4-olato)(2-methyl-8-quinolinato-N1,08)Aluminum (hereinafter abbreviated to Balq), for example, having a molecular structure shown in the formula (8) below. The electron transport layer 6 has a thickness of 200 Å, for example. This electron transport layer 6 also has the function of a hole blocking layer.

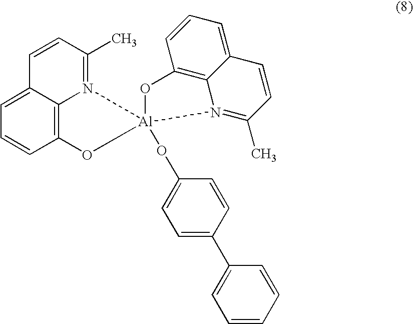

The electron injection layer 7 is made of a halogen compound such as lithium fluoride (LiF), for example. The electron injection layer 7 has a thickness of 10 Å, for example. The electron injection electrode 8 has a thickness of 2000 Å, for example.

While the FIrpic is employed as the first dopant of the light emitting layer 5 made of a triplet material, other ortho-metalated complexes which include, for example, bis(4,6-di-fluorophenyl-pyridinato-N,C2)platinum(acetylacetonate) (hereinafter abbrivaited to 4,6-F2ppyPt(acac)) having a molecular structure shown in the formula (9) below may also be employed.

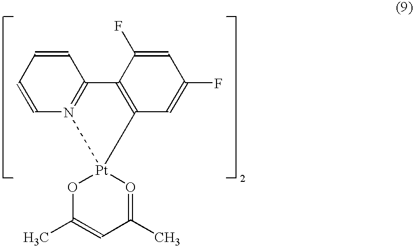

While the DPVBi is employed as the second dopant of the light emitting layer 5 which is made of a singlet material, other styryl compounds which include, for example, 4,4′-(Bis(9-ethyl-3-carbazovinylene)-1,1′-biphenyl (hereinafter abbreviated to BCzVBi) having a molecular structure shown in the formula (10) below or an anthracene derivative having a molecular structure shown in the formula (11) below or a perylene derivative having a molecular structure shown in the formula (12) below may also be employed.

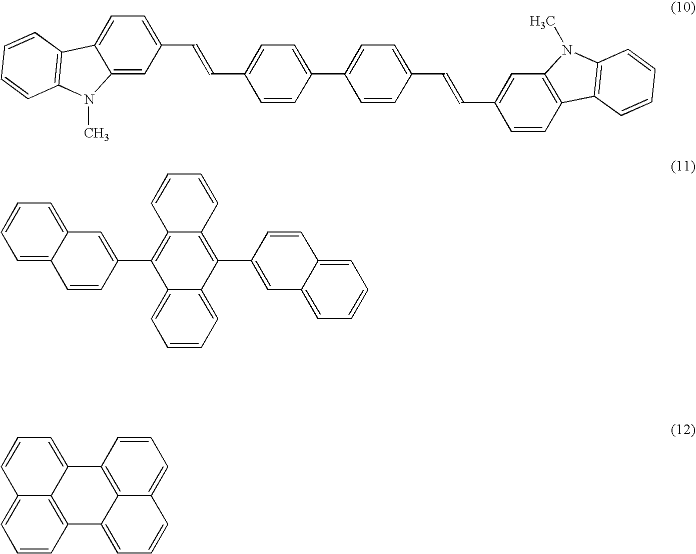

While the CBP is employed as the host material of the light emitting layer 5, other host materials which include 4,4′,4″-tri(N-carbazolyl)triphenylamine (hereinafter abbreviated to TCTA) having a molecular structure shown in the formula (13) below may also be employed.

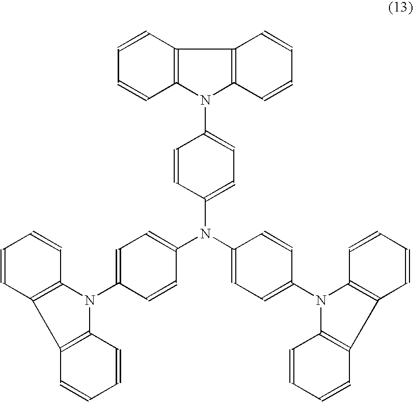

A method of fabricating the organic EL device according to the present embodiment will now be briefly described.

First, the substrate 1 bearing the hole injection electrode 2 is cleaned with a neutral detergent. After this, the substrate 1 is cleaned in deionized water for e.g. 10 min, and then cleaned in ethanol for e.g. 10 min, by an ultrasonic cleaning method, followed by cleaning using an ozone cleaner.

Next, on the hole injection electrode 2 residing on the substrate 1, the hole injection layer 3, hole transport layer 4, light emitting layer 5, electron transport layer 6, electron injection layer 7, and electron injection electrode 8 are formed in order by vacuum deposition. Each of the layers are vacuum deposited under a vacuum of 1×10⁻⁶ Torr, for example. In this case, substrate temperature is not controlled.

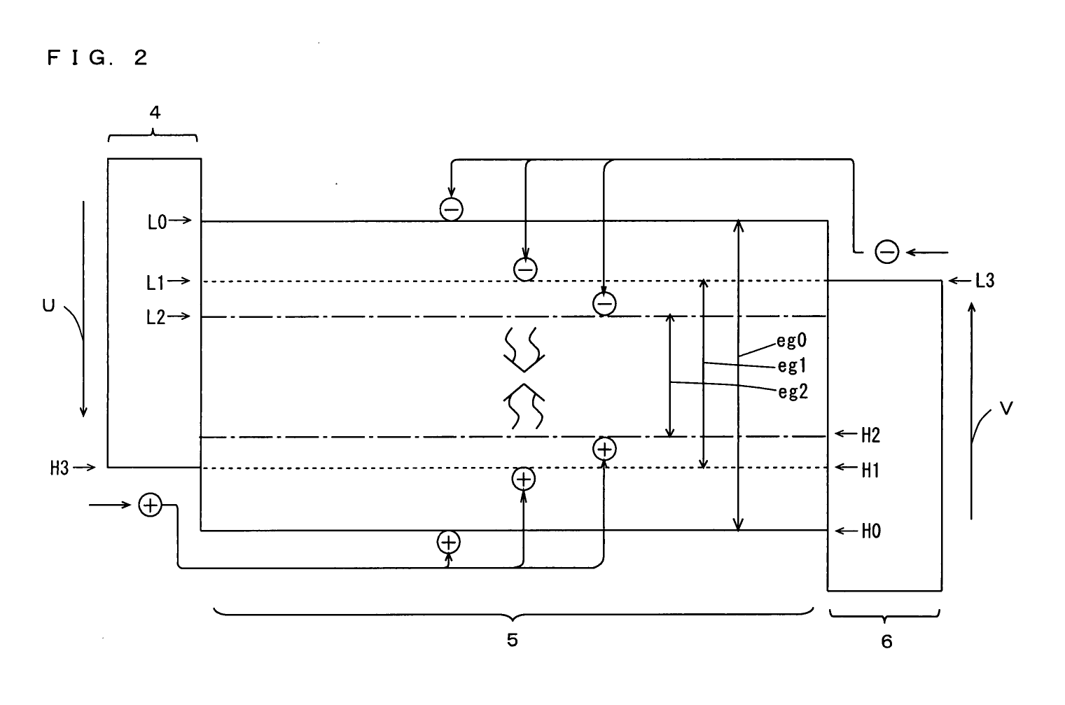

FIG. 2 is a schematic diagram showing exemplified energy levels of the lowest unoccupied molecular orbits (LUMO) and the highest occupied molecular orbits (HOMO) for the hole transport layer 4, light emitting layer 5, and electron transport layer 6 in the organic EL device 100 of the present embodiment as well as exemplified transfer processes of holes and electrons.

It is assumed, as shown in FIG. 2, that the HOMO level of the light emitting layer 5 host material is H0, the HOMO level of the light emitting layer 5 first dopant is H1, and the HOMO level of the light emitting layer 5 second dopant is H2.

It is also assumed that the LUMO level of the light emitting layer 5 host material is L0, the LUMO level of the light emitting layer 5 first dopant is L1, and the LUMO level of the light emitting layer 5 second dopant is L2.

With the light emitting layer 5, a relation of (second dopant HOMO level: H2)<(first dopant HOMO level: H1)<(host material HOMO level: H0) holds. The hole energy increases toward the direction of arrow U.

In addition, with the light emitting layer 5, a relation of (second dopant LUMO level L2)<(first dopant LUMO level: L1)<(host material LUMO level L0) holds. The electron energy increases toward the direction of arrow V.

Assuming that an energy gap eg0 is the energy difference between the HOMO level H0 and the LUMO level L0 of the host material of the light emitting layer 5; an energy gap eg1 is the energy difference between the HOMO level H1 and the LUMO level 1i of the first dopant; and an energy gap eg2 is the energy difference between the HOMO level H2 and the LUMO level L2 of the second dopant, then a relation as shown in the equation (14) below holds:
eg2<eg1<eg0 (14)

Since the energy gap eg1 of the first dopant made of a triplet material is greater than the energy gap eg2 of the second dopant made of a singlet material, the singlet excitation energy by the second dopant can be efficiently converted to light emission.

When drive voltage is applied between the hole injection electrode 2 and the electron injection electrode 8 in the organic EL device 100 of FIG. 1, holes supplied from the hole injection electrode 2 are injected to the hole injection layer 3, and electrons supplied from the electron injection electrode 8 are injected to the electron injection layer 7.

The holes injected to the hole injection layer 3 are transported via the hole transport layer 4 to the light emitting layer 5, and the electrons injected to the electron injection layer 7 are transported via the electron transport layer 6 to the light emitting layer 5.

The holes transported from the hole transport layer 4 to the light emitting layer 5 migrate to the HOMOs of the host material, first dopant, and second dopant.

Holes at the energy level H0 migrate to the energy level H1 or H2 in the light emitting layer 5. Since the second dopant has a carrier trapping ability superior to that of the first dopant, a greater amount of holes migrate to the energy level H2 than to the energy level H1.

The electrons transported from the electron transport layer 6 to the light emitting layer 5 migrate to the LUMOs of the host material, first dopant, and second dopant.

Electrons at the energy level L0 migrate to the energy level L1 or L2 in the light emitting layer 5. Since the second dopant has a carrier trapping ability superior to that of the first dopant, a greater amount of electrons migrate to the energy level L2 than to the energy level L1.

The holes at the energy level H2 and the electrons at the energy level L2 recombine in the light emitting layer 5 which thereby emits blue light. Also, the holes at the energy level H1 and the electrons at the energy level L1 recombine in the light emitting layer 5 which thereby emits blue light.

In the organic EL device 100 of the present embodiment, the light emitting layer 5 is doped with the first dopant of a triplet material and the second dopant of a singlet material that luminesces at the same wavelength as that of the first dopant, respectively. The inclusion of such first dopant with high luminous efficiency and chemically stable second dopant in the light emitting layer 5 enables high luminous efficiency and extended life of the organic EL device 100.

For more efficient use of the triplet energy by the first dopant, it is preferable that the LUMO level L1 of the first dopant is close to LUMO level L3 of an organic material of the electron transport layer 6.

For even more efficient use of the triplet energy by the first dopant, it is preferable that the HOMO level H1 of the first dopant is close to HOMO level H3 of an organic material of the hole transport layer 4.

Efficient use of the triplet energy-by the first dopant of a triplet material as described above will results in high efficiency light emission.

It is preferable that the difference between the emission peak wavelength of the first dopant and the emission peak wavelength of the second dopant is 20 nm or less. This prevents the light emitting layer 5 from emitting in a different color from a predetermined color.

It is more preferable that the difference between the emission peak wavelength of the first dopant and the emission peak wavelength of the second dopant is 10 nm or less. This sufficiently prevents the light emitting layer 5 from emitting in a difference color from a predetermined color.

The emission peak wavelength of the first dopant may be smaller than that of the second dopant. This facilitates the emission of the second dopant with a smaller energy gap, allowing the first dopant with high luminous efficiency and the chemically stable second dopant to contribute almost equally to light emission. This results in high efficiency and long life light emission.

In the present embodiment, the hole injection electrode 2 corresponds to a first electrode, the electron injection electrode 8 corresponds to a second electrode, and the organic EL device 100 corresponds to an organic electroluminescent device.

Note that the organic EL device 100 of the present embodiment can also be used to emit red or green light.

For red light emission, Bis(2-phenylbenzothiozolato-N,C2)Iridium(acetylacetonate) (hereinafter abbreviated to bt2Ir(acac)), a triplet material having a molecular structure shown in the formula below (15) or Bis(2-2′-benzothienyl)-pridinato-N,C3Iridium(acetylacetonate) (hereinafter abbreviated to btp2Ir(acac)), a triplet material having a molecular structure shown in the formula below (16) may be used, for example, as the first dopant of the light emitting layer 6, and an organic compound having a molecular structure shown in the formula (17) below may be used, for example, as the second dopant.

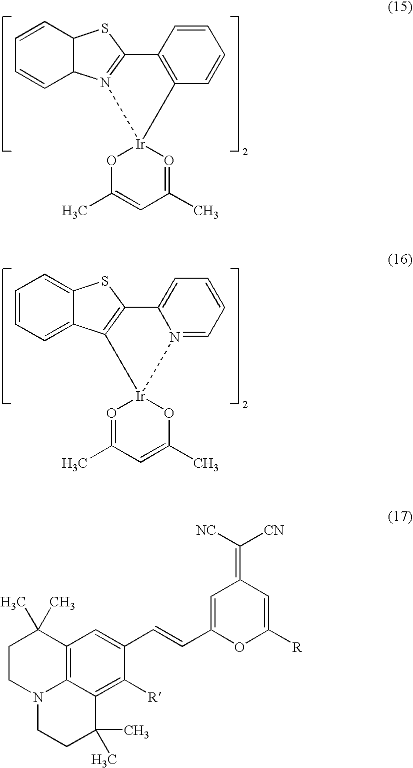

In the case where R in the formula (17) is tertiary-butyl (t-Bu) and R′ is a hydrogen atom (H), the formula (17) represents DCJTB.

In the case where R in the formula (17) is a propyl group and R′ is a hydrogen atom, the formula (17) represents DCJTI.

In the case where R in the formula (17) is t-Bu and R′ is OCH₃, the formula (17) represents DCJ.

When the organic EL device 100 of the present embodiment is used to emit green light, Tris(2-phenylpyridine)iridium (hereinafter abbreviated to Ir(ppy)₃), a triplet material having a molecular structure shown in the formula (18) below, tris(2-(4-methyl)phenylpyridine)iridium (hereinafter abbreviated to Ir(Meppy)₃), a triplet material having a molecular structure shown in the formula (19) below, or bis(7,8-benzoquinolinato-N,C3′)iridium(acetylacetonate) (hereinafter abbreviated to Ir(bzq)₃), a triplet material having a molecular structure shown in the formula (20) below, may for example be used as the first dopant of the light emitting layer 5.

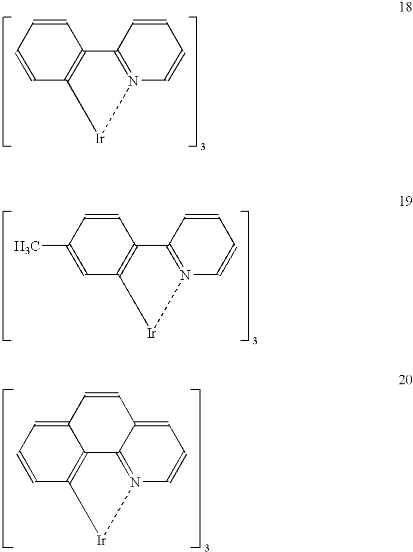

For green light emission, a coumarin derivative that is a singlet material having a molecular structure shown in the formula (21) below or a quinacridone derivative that is a singlet material having a molecular structure shown in the formula (22) below may for example be used as the second dopant of the light emitting layer 5.

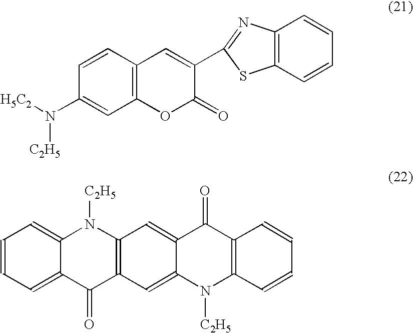

In the case where R and R′ in the formula (21) are each a hydrogen atom, the formula (21) represents C545T.

In the case where R in the formula (21) is t-Bu and R′ is a hydrogen atom, the formula (21) represents C545TB.

In the case where R in the formula (21) is a hydrogen atom and R′ is a methyl group (CH₃), the formula (21) represents C545MT.

### INVENTIVE EXAMPLE

An organic EL device of the inventive example is similar in structure to the organic EL device 100 of the above-described embodiment.

In the inventive example, an organic EL device 100 is measured for luminous efficiency and life by applying drive voltage between the hole injection electrode 2 and the electron injection electrode 8 in an organic EL device 100. As used herein the term life refers to the time it takes for the luminance value of the organic EL device 100 to be decreased to half the initial value.

The results were that the emission color of the organic EL device 100 was blue, luminous efficiency was 11 cd/A, and life was 150 hours.

### COMPARATIVE EXAMPLE

In the comparative example, an organic EL device was fabricated that is similar in structure to the organic EL device 100 of the inventive example except that the light emitting layer 5 is not doped with the second dopant made of a singlet material.

As with the inventive example, the organic EL device of the comparative example was measured for luminous efficiency and life by applying drive voltage between the hole injection electrode 2 and the electron injection electrode 8. The results were that the emission color of the organic EL device was blue, luminous efficiency was 10 cd/A, and life was 15 hours.

The foregoing results reveal that doping the light emitting layer 5 of the organic EL device 100 with the first dopant and the second dopant enables high luminous efficiency and markedly extended life of the organic EL device 100.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An organic electroluminescent device comprising a light emitting layer between a first electrode and a second electrode, wherein
said light emitting layer includes a first dopant made of a material capable of converting at least triplet excitation energy to an emission of a predetermined color and a second dopant made of a material capable of converting singlet excitation energy to an emission of the same color as said predetermined color.

2. The organic electroluminescent device according to claim 1, wherein
said predetermined color is blue.

3. The organic electroluminescent device according to claim 1, wherein
a difference between an emission peak wavelength of said first dopant and an emission peak wavelength of said second dopant is 20 nm or less.

4. The organic electroluminescent device according to claim 3, wherein
the emission peak wavelength of said first dopant is smaller than the emission peak wavelength of said second dopant.

5. The organic electroluminescent device according to claim 1, wherein
said first dopant is an ortho-metalated complex.

6. The organic electroluminescent device according to claim 5, wherein
said ortho-metalated complex has a molecular structure shown in formula (1) below: 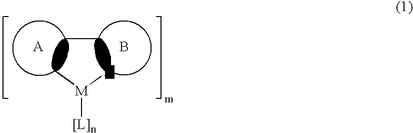
where a ring A is an aromatic hydrocarbon ring that may have a substituent or an aromatic heterocycle that may have a substituent; a group of said ring A and a group of said ring B may bond to form a ring that is fused to said ring A and said ring B; M is a platinum group element; L is a ligand; a value represented by m+n (m and n being integers) is equal to the valence of said platinum group element; and n represents an integer of 0≦n<m+n.

7. The organic electroluminescent device according to claim 6, wherein
m in said formula (1) is two, and L has a molecular structure shown in formula (L1) below: 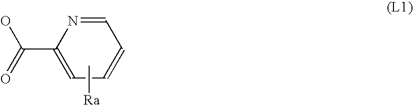
where Ra is a hydrogen atom, a halogen atom or a substituent.

8. The organic electroluminescent device according to claim 6, wherein
m in said formula (1) is two, and L has a molecular structure shown in formula (L2) below: 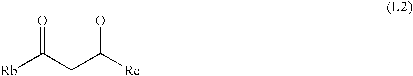
where Rb and Rc are the same or different, each being a hydrogen atom, a halogen atom or a substituent.

9. The organic electroluminescent device according to claim 6, wherein
said platinum group element is iridium, platinum, osmium, ruthenium, rhodium or palladium.

10. The organic electroluminescent device according to claim 1, wherein
said second dopant is a styryl compound, an anthracene derivative or a perylene derivative.

11. The organic electroluminescent device according to claim 10, wherein
said styryl compound has a molecular structure shown in formula (2) below: [chemical structure]
